(19) United States
(12) Patent Application Publication
(10) Pub. No.: US 2006/0160028 A1
(43) Pub. Date: Jul. 20, 2006

(54) Method of forming fine patterns of a semiconductor device

(76) Inventors: Hyung-Rae Lee, Seoul (KR); Yool Kang, Gyeonggi-do (KR); Sang-Gyun Woo, Gyeonggi-do (KR); Man-Hyoung Ryoo, Gyeonggi-co (KR); Suk-Joo Jee, Gyeonggi-do (KR)

Correspondence Address: Robert W. Glatz;Myers Bigel Sibley & Sajovec, P.A., P. O. Box 37428, Raleigh, NC, 27627, US

(21) Appl. No.: 11/328,404

(22) Filed: Jan. 9, 2006

(30) Foreign Application Priority Data
Jan. 17, 2005 (KR) 2005-04312

(51) Int. Cl. G03F 7/00

(52) U.S. Cl. 430/312

(57) ABSTRACT

Methods of forming fine patterns of a semiconductor device include forming a positive first photoresist layer on a semiconductor substrate, including initiating an exposure reaction at a first dose. The first photoresist layer is exposed and developed to form first photoresist patterns. A second photoresist layer is formed on a region of the semiconductor substrate including the first photoresist patterns, including terminating an exposure reaction at a second dose no greater than the first dose. The second photoresist layer is exposed and developed to form second photoresist patterns between the first photoresist patterns. Methods of forming fine patterns having a negative first photoresist layer are also provided.

### CROSS-REFERENCE TO RELATED APPLICATION

This application is related to and claims priority from Korean Patent Application No. 10-2005-0004312, filed Jan. 17, 2005, the contents of which are hereby incorporated herein by reference in their entirety.

### BACKGROUND OF THE INVENTION

The present invention relates to methods of fabricating semiconductor devices, and more particularly, to methods of forming patterns in a semiconductor device.

Semiconductor devices may be fabricated using several distinct processes. For example, the semiconductor devices may be fabricated using a photolithography process, an etching process, a thin film deposition process, a diffusion process, and so forth at different points in the fabrication process. The photolithography process may particularly directly affect the characteristics of fine patterns formed in the semiconductor devices. Accordingly, the photolithography process typically plays a major role in the fabrication of highly integrated semiconductor devices.

The photolithography process generally includes a coating step for forming a photoresist layer on a semiconductor substrate, an exposure step of selectively irradiating light on a predetermined region of the photoresist layer using a photomask, and a development step for selectively removing the exposed photoresist layer to form a photoresist pattern. The photoresist pattern may then be used as a mask while a subsequent etching, ion implantation process and/or the like process is carried out.

Typically, the photoresist used for the photolithography process is a material in which resolution or a cross-linking reaction occurs due to light energy so that the materials dissolution characteristics change. The photoresist can be generally classified as a positive photoresist or a negative photoresist. The negative photoresist has been commercially available, however, it is well known in the art that the negative photoresist usually has a lower resolution than the positive photoresist.

In recent years, as the semiconductor devices become more highly integrated, a method of increasing pattern resolution at the time of exposure is of interest. Resolution (R), according to the Rayleigh's equation typically used in the art, is as follows.

$$R - {K}_{1} \times \frac{λ}{NA} \qquad ( 1 )$$

where K₁ is a constant, λ is a wavelength, and NA is a numerical aperture. The resolution R is proportional to the wavelength λ, and is in inverse proportion to the numerical aperture NA. A light source having a short wavelength may be used or a method of increasing the numerical aperture NA of a lens may be used in order to enhance the resolution.

In order to enhance the resolution, many light sources having a short wavelength have been developed. For example, a photolithography process is known using a G-line laser having a wavelength of 436 nm, an I-line laser having a wavelength of 365 nm, a KrF laser having a wavelength of 248 nm, an ArF laser having a wavelength of 193 nm, and an F₂ laser having a wavelength of 157 nm, as a light source. In addition, a process using X-ray and electronic beams as light sources has been developed. As such, development of short wavelength light sources and development on the photoresist corresponding to the same are important for photolithography processes.

As the light sources described above have a short wavelength, the photoresist typically needs to be highly sensitive. In a photolithography process using a light source having a short wavelength, such as a KrF or ArF laser, a chemically amplified resist is typically used to enhance the sensitivity. In particular, in a photoresist used in the photolithography process using a light source having a short wavelength, such as an ArF laser, acid generation is typically initiated by an exposure process, and amplification of the generated acid or cross-link due to reaction with the generated acid is typically caused by a post-exposure bake process.

The positive photoresist generally has a characteristic that a photo acid generator (PAG) generates strong acid ions (H+) by exposure energy, and the strong acid ions, which have already been generated, act as catalysts by thermal energy due to the post-exposure bake process so that a structure of the photoresist is changed to enable resin to be readily dissolved in a developing step.

On the contrary, the negative photoresist has a characteristic that the strong acid ions typically act as catalysts for the photoresist to have insolubility so as to make polymers of an exposed region bonded to each other to be co-polymerized.

As such, the chemically amplified resist typically has a characteristic that causes a very sensitive photo reaction using small exposure energy, while it is also generally very sensitive to contamination due to basic components such as ammonia and amine. When the acid generated by the exposure is lost by the basic component present on the substrate or in the air, a tail and/or footing may be formed in the pattern.

A photoresist that reacts to a light source having a short wavelength is generally more sensitive to a contamination component, such as amine, so that the contamination problem due to the amine or the like may become severe when the photolithography process using the light source having a short wavelength is employed. For example, the contamination problem due to the ammonia or amine group generally becomes more severe in a photolithography process using the ArF laser as a light source than a photolithography process using the KrF laser as a light source. Accordingly, a chemical filter for removing the amine group or the like may be employed so as not to expose the ammonia or amine group to the photolithography process.

As such, it is generally not easy to realize fine patterns using a photoresist that is very sensitive to the light source or the contamination source. Various methods for forming the fine patterns have been proposed. Among these methods, a method of forming a fine pattern using double exposure has been proposed.

A method of forming a fine pattern is disclosed in U.S. Pat. No. 5,686,223 entitled “Method for reduced pitch lithography” to Cleeves. As described in Cleeves, an image reversal process is carried out to perform two photolithography processes. In particular, the image reversal process is carried out using ammonia (NH₃). However, the ammonia may cause a process failure in a process using a photoresist that reacts to a short wavelength, such as ArF.

### SUMMARY OF THE INVENTION

Embodiments of the present invention include methods of forming fine patterns of a semiconductor device. A positive first photoresist layer is formed on a semiconductor substrate, including initiating an exposure reaction at a first dose. The first photoresist layer is exposed and developed to form first photoresist patterns. A second photoresist layer is formed on a region of the semiconductor substrate including the first photoresist patterns, including terminating an exposure reaction at a second dose no greater than the first dose. The second photoresist layer is exposed and developed to form second photoresist patterns between the first photoresist patterns.

In other embodiments, the second photoresist layer is either a positive photoresist layer or a negative photoresist layer. Exposing and developing the first photoresist layer and exposing and developing the second photoresist layer may include exposing the photoresist layers to a same type of light source. The type of light source may be a G-line, an I-line, a KrF laser or an ArF laser.

In further embodiments, the first and second photoresist layers are formed of chemically amplified resist layers. The chemically amplified resist layers may include a photo acid generator (PAG). The PAG within the first photoresist layer may have a concentration lower than that of the PAG within the second photoresist layer. The second photoresist layer may be a positive photoresist layer.

In other embodiments, the chemically amplified resist layers include a quencher. The quencher within the first photoresist layer may have a concentration higher than that of the quencher within the second photoresist layer.

In further embodiments, the first and second photoresist layers are formed of resist layers for G-line or I-line. The resist layers for G-line or I-line may include a photo acid compound (PAC). The PAC within the first photoresist layer may have a concentration lower than that of the PAC within the second photoresist layer.

In yet other embodiments, methods of forming fine patterns of a semiconductor device include forming a negative first photoresist layer on a semiconductor substrate, including terminating an exposure reaction at a first dose. The first photoresist layer is exposed and developed to form first photoresist patterns. A second photoresist layer is formed on a region of the semiconductor substrate including the first photoresist patterns, including initiating an exposure reaction at a second dose no less than the first dose. The second photoresist layer is exposed and developed to form second photoresist patterns between the first photoresist patterns. The second photoresist layer may be either a positive photoresist layer or a negative photoresist layer.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1 and 2 are graphs showing illustrating characteristics of a general photoresist layer.

FIG. 3 is a flow chart illustrating methods of forming fine patterns in accordance with some embodiments of the present invention.

FIGS. 4A, 4B, 5A and 5B are graphs showing response characteristics according to a dose of irradiating photoresist layers used in some embodiments of the present invention.

FIGS. 6, 7A, 7B, 8, 9, 10A, 10B and 11 are cross-sectional views illustrating methods of forming fine patterns of a semiconductor device in accordance with some embodiments of the present invention.

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

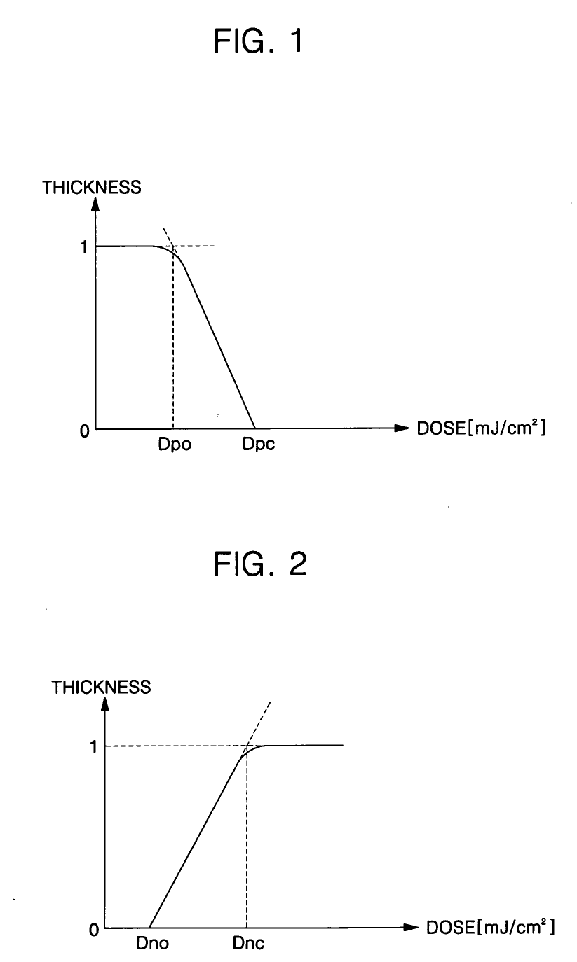

FIGS. 1 and 2 are graphs illustrating the characteristics of a photoresist layer according to doses. More partiularly, FIG. 1 is a graph showing a response characteristic of a positive photoresist layer, and FIG. 2 is a graph showing a response characteristic of a negative photoresist layer. Referring to FIGS. 1 and 2, the X axis denotes doses that are plotted on a log₁₀ scale and the Y axis denotes layer thickness for an exposure process that is carried out while the dose with respect to the photoresist layer having a constant thickness is changed, and the thickness of the photoresist layer is changed after a fixed development step is carried out.

Referring to FIGS. 1 and 2, in the positive photoresist layer, an exposure reaction is initiated at a reaction initiating dose Dpo and the thickness of the photoresist layer substantially starts to decrease as shown in FIG. 1. As the dose increases, the thickness of the positive photoresist layer after development further decreases, so that when the dose reaches a threshold dose Dpc, the exposure reaction is completely carried out, thereby making the thickness of the positive photoresist layer substantially zero.

On the contrary, in the negative photoresist layer, an exposure reaction is initiated at a reaction initiating dose Dno and the thickness of the photoresist layer substantially starts to increase as shown in FIG. 2. As the dose increases, the thickness of the negative photoresist layer after development further increases, so that when the dose reaches a threshold dose Dnc, the exposure reaction is completely carried out, and, thus, the thickness of the negative photoresist layer after the development is substantially the same as that before the exposure.

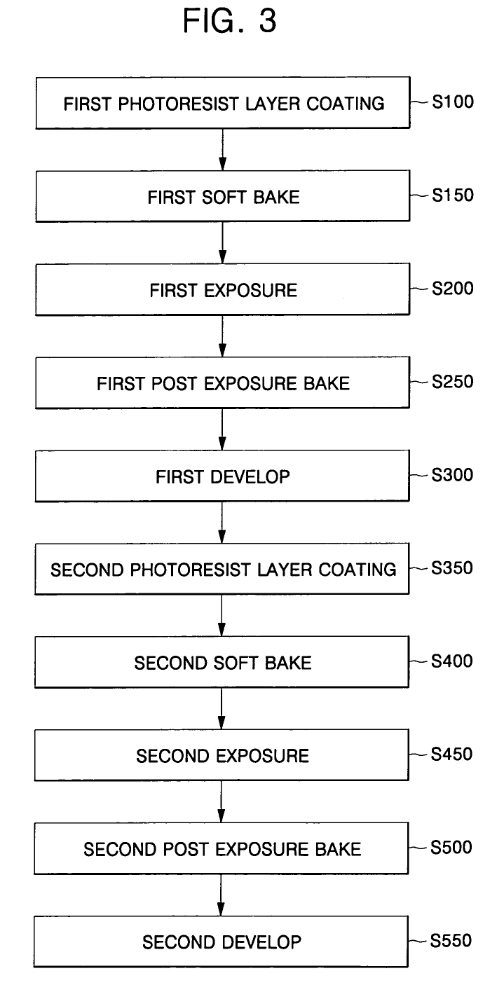

FIG. 3 is a process flow chart illustrating methods of forming fine patterns of a semiconductor device in accordance with some embodiments of the present invention. As shown in the embodiments of FIG. 3, the methods include two photolithography processes. Each of the photolithography processes includes photoresist layer coating, soft bake, exposure, post-exposure bake, and development processes. That is, a first photolithography process including a first photoresist layer coating process (block S100), a first soft bake process (block S150), a first exposure process (block S200), a first post-exposure bake process (block S250), and a first development process (block S300) are carried out to form first photoresist patterns on a semiconductor substrate, in particular, on an underlying layer to be patterned.

Subsequently, a second photoresist layer is coated on the semiconductor substrate having the first photoresist patterns (block S350), and a second photolithography process including a second soft bake process (block S400), a second exposure process (block S450), a second post-exposure bake process (block S500), and a second development process (block S550) is carried out to form second photoresist patterns between the first photoresist patterns. Subsequently, an etching process using the first and second photoresist patterns as etch masks can be carried out so that the underlying layer can be patterned to have a desired fine pattern.

According to some embodiments of the present invention, photoresist layers having polarized response characteristics are used for the photolithography processes, so that additional affects on the first photoresist patterns that are already formed on the semiconductor substrate during the second exposure (block S450) may be limited or even prevented.

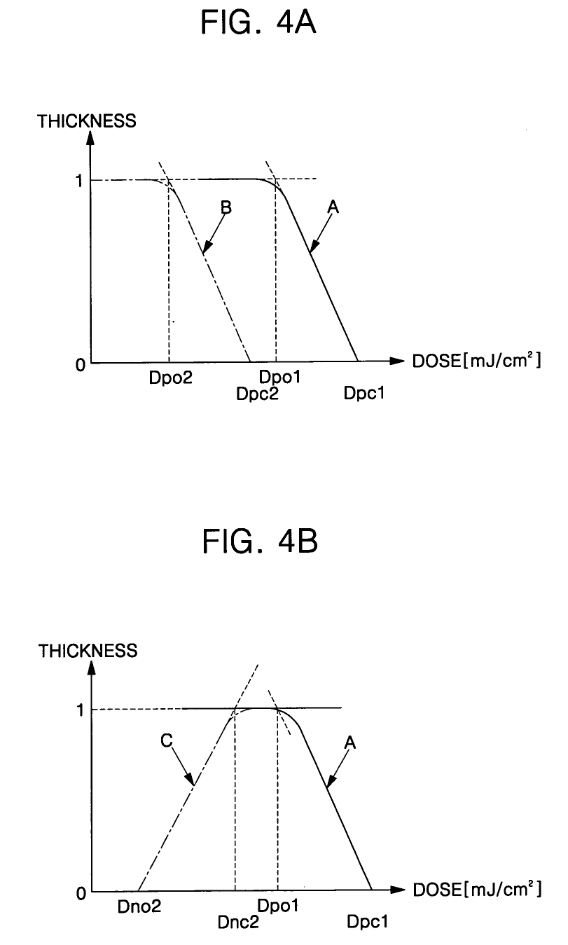

FIGS. 4A and 4B are graphs showing response characteristics according to a dose of photoresist layers used in an embodiment of the present invention. In particular, FIG. 4A is a graph showing a response characteristic A of the first photoresist layer and a response characteristic B of the second photoresist layer when the first and second photoresist layers are positive photoresist layers, and FIG. 4B is a graph showing a response characteristic A of the first photoresist layer and a response characteristic C of the second photoresist layer when the first and second photoresist layers are positive and negative photoresist layers, respectively.

Referring to FIGS. 4A and 4B, when the first photoresist layer is a positive photoresist layer, the second photoresist layer is formed of a positive or negative photoresist layer where an exposure reaction is terminated or saturated at a dose equal to or less than a reaction-initiating dose Dpo1 of the first photoresist layer. That is, a threshold dose of the second photoresist layer has a value equal to or less than the reaction-initiating dose Dpo1 of the first photoresist layer.

When the second photoresist layer is a positive photoresist layer, as shown in FIG. 4A, an exposure reaction of the second photoresist layer is terminated or saturated at a threshold dose Dpc2 equal to or less than the reaction-initiating dose Dpo1 of the first photoresist layer. Furthermore, when the second photoresist layer is a negative photoresist layer, as shown in FIG. 4B, its exposure reaction is terminated or saturated at a threshold dose Dnc2 equal to or less than the reaction-initiating dose Dpo1 of the first photoresist layer. In this case, an exposure reaction of the first photoresist layer is initiated at a dose equal to or more than the threshold dose of the second photoresist layer, so that additional exposure of the first photoresist patterns can be suppressed and the second photoresist layer can still be sufficiently exposed during the second exposure (block S450 in FIG. 3).

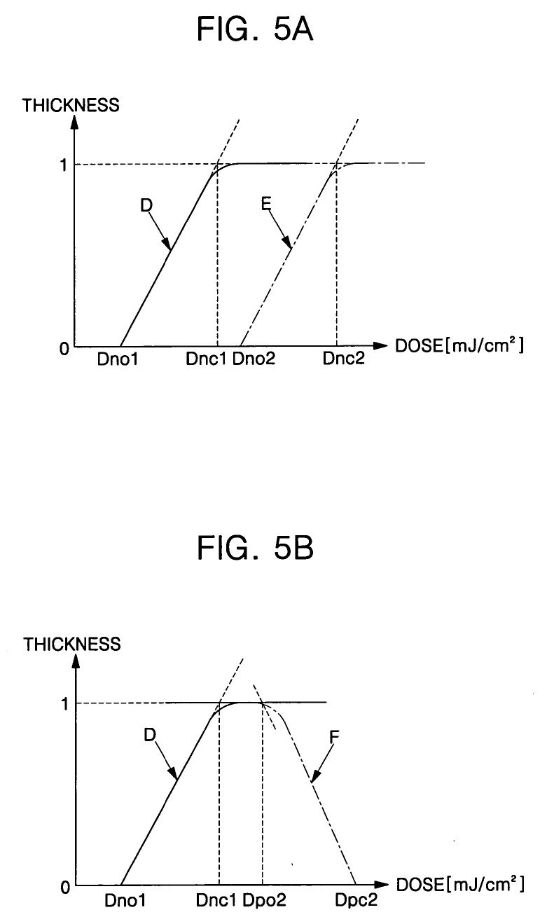

FIGS. 5A and 5B are graphs showing response characteristics according to a dose of photoresist layers used in further embodiments of the present invention. In particular, FIG. 5A is a graph showing a response characteristic D of the first photoresist layer and a response characteristic E of the second photoresist layer when the first and second photoresist layers are negative photoresist layers, and FIG. 5B is a graph showing a response characteristic D of the first photoresist layer and a response characteristic F of the second photoresist layer when the first and second photoresist layers are negative and positive photoresist layers, respectively.

Referring to FIGS. 5A and 5B, when the first photoresist layer is a negative photoresist layer, the second photoresist layer is formed of a positive or negative photoresist layer where an exposure reaction is initiated at a dose equal to or more than a threshold dose Dnc1 of the first photoresist layer. That is, a reaction-initiating dose of the second photoresist layer has a value equal to or more than the threshold dose Dnc1 of the first photoresist layer. When the second photoresist layer is a negative photoresist layer, as shown in FIG. 5A, an exposure reaction of the second photoresist layer is initiated at a dose Dno2 equal to or more than the threshold dose Dnc1 of the first photoresist layer. Furthermore, when the second photoresist layer is a positive photoresist layer, as shown in FIG. 5B, an exposure reaction of the second photoresist layer is initiated at a reaction-initiating dose Dpo2 equal to or more than the threshold dose Dnc1 of the first photoresist layer.

When a G-line or an I-line is employed as a light source used for the exposure process, photoresists for the G-line or I-line including a photo acid compound (PAC) may be used as photoresists for forming the photoresist layers. Furthermore, when a KrF or ArF laser is employed as a light source used for the exposure process, chemically amplified resists including a photo acid generator (PAG) may be used as photoresists for forming the photoresist layers. Doses to the photoresist layers can be adjusted by adjusting the concentration of the PAC or PAG. For example, threshold doses and reaction-initiating doses of the photoresist layers can be reduced by increasing the concentration of the PAC or PAG.

As described above with reference to FIGS. 4A, 4B, 5A and 5B, respectively, response characteristics of the first and second photoresist layers can be made different by properly adjusting the concentration of the PAC or PAG. As described above with reference to FIGS. 4A and 4B, when the first photoresist layer is formed of a positive photoresist layer, the concentration of the PAC or PAG of the first photoresist layer may be lower than that of the second photoresist layer. In this case, the second photoresist layer may be a positive or negative photoresist layer. In addition, as described above with reference to FIGS. 5A and 5B, when the first photoresist layer is formed of a negative photoresist layer, the concentration of the PAC or PAG of the first photoresist layer may be higher than that of the second photoresist layer.

Furthermore, the positive photoresist layer formed of the chemically amplified resists may include at least a quencher in some embodiments. The quencher may be used as an additive for reducing performance degradation due to inactivation of acid resulting from the delay after exposure, and may be a basic compound. The threshold dose or reaction-initiating dose of the positive photoresist layer can be adjusted by adjusting the concentration of the quencher. For example, the threshold dose or reaction-initiating dose of the positive photoresist layer can increase by increasing the concentration of the quencher. More particularly, as described above with reference to FIG. 4A, when the first and second photoresist layers are formed of positive photoresist layers, the quencher concentration of the first photoresist layer may be higher than that of the second photoresist layer.

According to some embodiments of the present invention, fine patterns can be formed on a semiconductor substrate by carrying out two photolithography processes using photoresist layera having polarized response characteristics resulting from the response characteristic of the photoresist layer depending on a dose during the exposure process as described above.

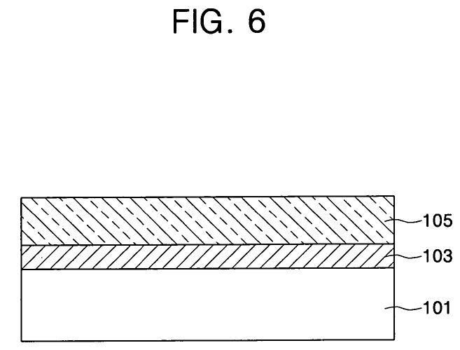

FIGS. 6, 7A, 7B, 8, 9, 10A, 10B and 11 are cross-sectional views illustrating methods of forming fine patterns in a semiconductor device in accordance with some embodiments of the present invention. Hereinafter, the description of these figures will be given including references to FIGS. 3, 4A, and 5B.

Referring to FIGS. 3 and 6, an underlying layer 103 can be formed on a semiconductor substrate 101. The underlying layer 103 may be an insulating layer, such as a silicon oxide layer and/or a silicon nitride layer. The underlying layer 103 may be a conductive layer, such as a polysilicon layer. An anti-reflective layer may be formed on an entire surface of the semiconductor substrate having the underlying layer 103. The formation of the anti-reflective layer may not be included in some embodiments.

A first photoresist layer 105 is formed on an entire surface of the semiconductor substrate having the underlying layer 103 (block S100 of FIG. 3). The first photoresist layer 105 may be a positive or negative photoresist layer. The first photoresist layer 105 may be formed, for example, by spin-coating a photoresist. In this case, the first photoresist layer 105 may be formed of a chemically amplified photoresist layer, a photoresist layer for G-line and/or a photoresist layer for I-line.

Before the first photoresist layer 105 is formed, a contact enhancement treatment may be performed. The contact enhancement treatment may be performed, for example, using hexamethyidisilazane (HMDS).

Subsequently, a first soft bake can be performed on the first photoresist layer 105. (block S150 of FIG. 3). The first soft bake may be used as a process for removing a solvent component remaining within the first photoresist layer 105. That is, the photoresist containing the solvent may be in a fluid state having a viscosity allowing spin-coating to be carried out, so that the solvent component within the first photoresist layer, which has been formed by completing the spin-coating, is to be removed. Most of the solvents are generally removed by the thermal energy of the first soft bake, so that the first photoresist layer 105 can be converted from the fluid state to the solid state. The first soft bake can be performed, for example, at a temperature of 100° C. to 135° C.

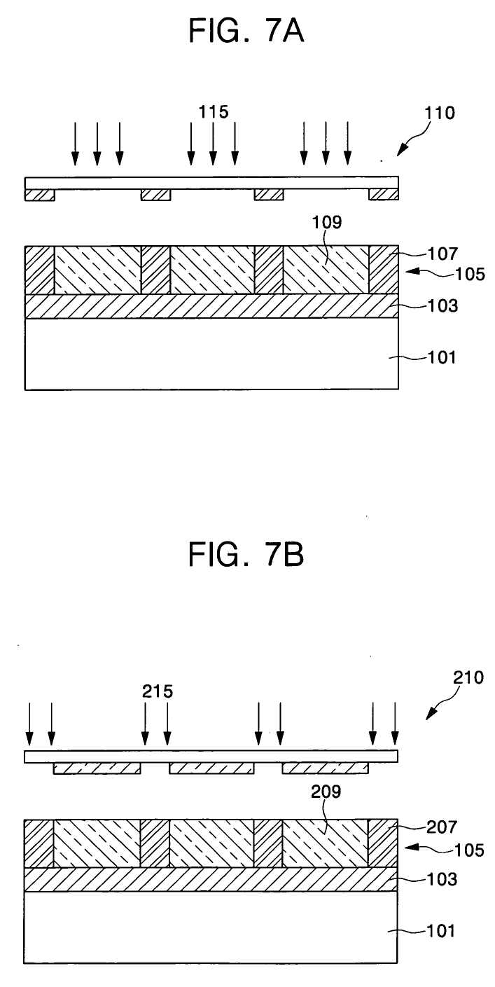

Referring to FIGS. 3 and 7A, when the first photoresist layer 105 is formed of a positive photoresist layer, a first exposure process that uses a first light source 115 and a first photomask 110 can be performed on the first photoresist layer 105 (block S200 of FIG. 3). That is, a mask image of the first photomask 110 can be transferred onto the first photoresist layer 105 so that the first photoresist layer of the exposed region undergoes a photochemical reaction. The first exposure process may be carried out in a stepper and/or scanner manner. The first photomask 110 may be a binary mask or a phase shift mask. A G-line having a wavelength of 436 nm, an I-line having a wavelength of 365 nm, a KrF laser having a wavelength of 248 nm and/or an ArF laser having a wavelength of 193 nm may be employed as the first light source 115.

More particularly, when the first light source 115 is a KrF and/or ArF laser, the photoresist layer 105 can be formed of a chemically amplified photoresist layer. The PAG within the first photoresist layer 105 exposed by the first light source 115 produces an acid catalyst, such as strong acid ions (H+), thereby forming a first exposed region 109 including the strong acid ions. A region that is not exposed by the first light source 115 may be referred to herein as a first non-exposed region 107. Subsequently, a first post-exposure bake may be carried out on the first photoresist layer 105 having the first exposed region 109 and the first non-exposed region 107 (block S250 of FIG. 3). The first post-exposure bake supplies energy that may enable the acid catalyst produced within the first photoresist layer 105 by the first exposure to effectively catalyze a co-polymerizing reaction. The thermal energy resulting from the first post-exposure bake can change a structure of the first exposed region 109 to enable the first exposed region to be readily dissolved in a developer by making the already produced strong acid ions (H+) act as a catalyst to decrease the molecular weight of polymer.

When a G-line and/or an I-line is used as the first light source 115, the first photoresist layer 105 can be formed of a photoresist layer for G-line and/or I-line. Subsequently, the first post-exposure bake can be performed. The first post-exposure bake can act to decrease wrinkles, which may occur at an interface surface between the first exposed region 109 and the first non-exposed region 107.

Referring to FIGS. 3 and 7B, in some embodiments when the first photoresist layer 105 is formed of a negative photoresist layer, a first exposure process can be carried out on the first photoresist layer 105 using a first light source 215 and a first photomask 210 (block S200 of FIG. 3). A region of the first photoresist layer 105 exposed by the first light source 215 may be referred to herein as a first exposed region 207, and a region which is not exposed by the first light source 215 may be referred to herein as a first non-exposed region 209. A mask image of the first photomask 110 is transferred onto the first photoresist layer 105, so that the first photoresist layer 105 of the exposed region undergoes a photochemical reaction that renders it selectively soluble with respect to a developer in a subsequent development process (block S300 of FIG. 3). The first photomask 210 may be a binary mask and/or a phase shift mask. A G-line, an I-line, a KrF laser and/or an ArF laser may be employed as the first light source 215.

More particularly, when the KrF laser and/or the ArF laser is employed as the first light source 215, the photoresist layer 105 may be formed of a chemically amplified resist layer. Subsequently, a first post-exposure bake can be carried out on the first photoresist layer 105 having the first exposed region 207 and the first non-exposed region 209 (block S250 of FIG. 3). The first post-exposure bake supplies energy that may enable the acid catalyst produced within the resist layer 105 by the first exposure process (block S200 of FIG. 3) to effectively catalyze a co-polymerizing reaction. The thermal energy from the first post-exposure bake (block S250 of FIG. 3) may enable the strong acid ions (H+) produced by the first exposure process (block S200 of FIG. 3) to catalyze bonding among polymers of the first exposed region 207 to become co-polymerized, thereby rendering the first exposed region 207 insoluble.

When the G-line and/or the I-line is employed as the first light source 215, the first photoresist layer 105 may be formed of a photoresist layer for G-line and/or I-line. Subsequently, a first post-exposure bake (block S250 of FIG. 3) can be carried out on the first photoresist layer 105 having the first exposed region 207 and the first non-exposed region 209. The first post-exposure bake (S250) can act to decrease wrinkles that may occur at an interface surface between the first exposed region 209 and the first non-exposed region 207. The first post-exposure bake (block S250 of FIG. 3) can be performed, for example, at a temperature of 100° C. to 120° C.

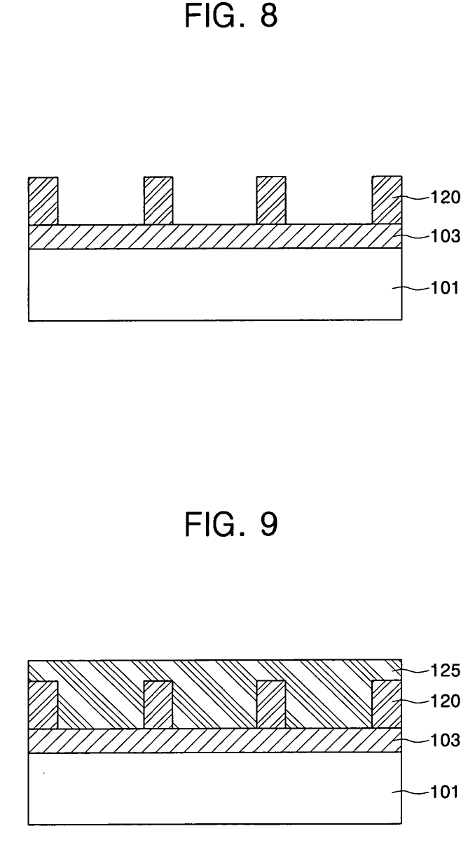

Referring now to FIGS. 3 and 8, a first development process is carried out on the first photoresist layer 105 (block S300 of FIG. 3). The first development process (block S300 of FIG. 3) provides a pattern shape by using a solubility difference between the exposed region and the non-exposed region of the first photoresist layer 105 with respect to a developer, such as an alkali aqueous solution.

More particularly, when the first photoresist layer 105 is formed of a positive photoresist layer, the photoresist layer of the first exposed region 109 may be removed by the first development process (block S300 of FIG. 3) and only the photoresist layer of the first non-exposed region 107 remains, thereby forming first photoresist patterns 120.

On the contrary, when the first photoresist layer 105 is formed of a negative photoresist layer, the photoresist layer of the first exposed region 207 remains by the first development process (S300), and the photoresist layer of the first non-exposed region 209 is removed by the first development process (S300), thereby forming first photoresist patterns 120.

Referring to FIGS. 3 and 9, a second photoresist layer 125 covering the first photoresist patterns 120 is formed on an entire surface of the semiconductor substrate where the first photoresist patterns 120 are formed (block S350 of FIG. 3).

When the first photoresist patterns 120 are formed of a positive photoresist layer having the response characteristic A of the first photoresist layer described above with reference to FIGS. 4A and 4B, the second photoresist layer 125 may be formed of a positive photoresist layer having the response characteristic B of the second photoresist layer described above with reference to FIG. 4A, or a negative photoresist layer having the response characteristic C of the second photoresist layer described above with reference to FIG. 4B.

When the first photoresist patterns 120 are formed of a negative photoresist layer having the response characteristic D of the first photoresist layer described above with reference to FIGS. 5A and 5B, the second photoresist layer 125 may be formed of a negative photoresist layer having the response characteristic E of the second photoresist layer described above with reference to FIG. 5A, or a positive photoresist layer having the response characteristic F of the second photoresist layer described above with reference to FIG. 5B.

Subsequently, a second soft bake can be carried out on the second photoresist layer 125 (block S400 of FIG. 3). The second soft bake (block S400 of FIG. 3) in some embodiments is carried out at a temperature lower than the temperature of the first soft bake and the temperature of the first post-exposure bake. This temperature selection may minimize effects due to the temperature on the first photoresist patterns 120. However, the temperature of the second soft bake (block S400 of FIG. 3) should be sufficient for providing a soft bake. In other words, the second soft bake (block S400 of FIG. 3) can be carried out at a temperature lower than the temperature of the first soft bake and the temperature of the first post-exposure bake, and can be carried out at a temperature, for example, of 90° C. or more.

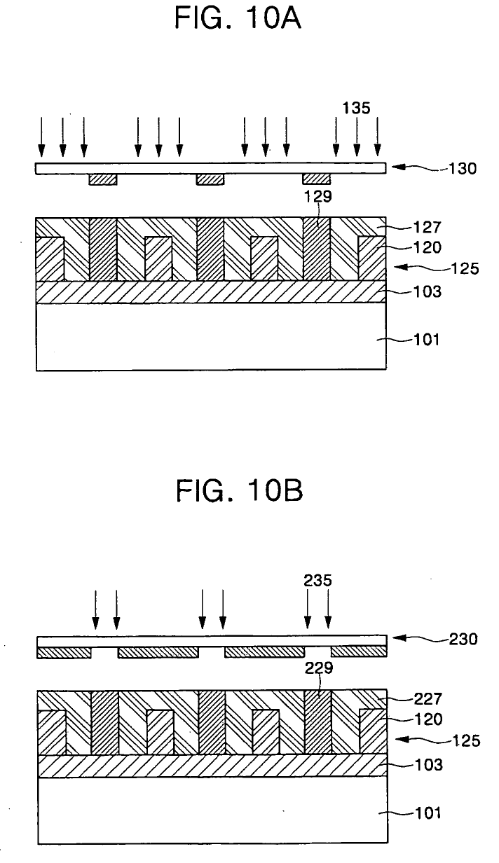

Referring to FIGS. 3 and 10A, when the second photoresist layer 125 is formed of a positive photoresist layer, a second exposure process can be performed using a second light source 135 and a second photomask 130 (block S450 of FIG. 3). The second photomask 130 may be a binary mask and/or a phase shift mask. A region of the second photoresist layer 125 exposed by the second light source 135 may be referred to herein as a second exposed region 127 and a region that is not exposed by the second light source 135 may be referred to herein as a second non-exposed region 129. In this case, the first photoresist patterns 120 may be formed of a positive or negative photoresist layer.

More particularly, the first photoresist patterns 120 and the second photoresist layer 125 can be formed of positive photoresist layers having the response characteristic A of the first photoresist layer and the response characteristic B of the second photoresist layer, respectively as described above with reference to FIG. 4A. Accordingly, an exposure reaction of the second photoresist layer 125 may be terminated or saturated at a threshold dose Dpc2 equal to or less than the reaction-initiating dose Dpo1 of the first photoresist patterns 120. Exposure reactions of the first photoresist patterns 120 are initiated at a dose more than the threshold dose of the second photoresist layer 125, so that additional exposure of the first photoresist patterns 120 can be suppressed even when an exposure process is carried out on the second photoresist layer 125. Consequently, the first photoresist patterns 120 are not substantially affected by the exposure process of the second photoresist layer 125.

The first photoresist patterns 120 and the second photoresist layer 125 can be formed of photoresist layers having the response characteristic D of the first photoresist layer and the response characteristic F of the second photoresist layer, respectively as described above with reference to FIG. 5B. That is, the first photoresist patterns 120 may be formed of a negative photoresist layer having the response characteristic D of the first photoresist layer as described above with reference to FIG. 5B, and the second photoresist layer 125 may be formed of a positive photoresist layer having the response characteristic F of the second photoresist layer as described above with reference to FIG. 5B. Accordingly, an exposure reaction of the second photoresist layer 125 may be initiated at an initiating dose equal to or more than the threshold dose Dnc1 of the first photoresist patterns 120 and terminated or saturated at the threshold dose Dpc2 of the second photoresist layer shown in FIG. 5B. That is, the exposure process of the second photoresist layer 125 may enable the first photoresist patterns 120 to be substantially cured or further stabilized.

For the embodiments shown in FIGS. 3 and 10B, when the second photoresist layer 125 is formed of a negative photoresist layer, a second exposure process can be carried out using a second light source 235 and a second photomask 230 (block S450 of FIG. 3). The second photomask 230 may be a binary mask and/or a phase shift mask. A region of the second photoresist layer 125 exposed by the second light source 235 may be referred to herein as a second exposed region 229, and a region that is not exposed by the second light source 235 may be referred to herein as a second non-exposed region 227. In this case, the first photoresist patterns 120 may be formed of a positive or negative photoresist layer.

More particularly, the first photoresist patterns 120 and the second photoresist layer 125 can be formed of photoresist layers having the response characteristic A of the first photoresist layer and the response characteristic C of the second photoresist layer, respectively as described above with reference to FIG. 4B. That is, the first photoresist patterns 120 may be formed of a positive photoresist layer having the response characteristic A of the first photoresist layer as described above with reference to FIG. 4B, and the second photoresist layer 125 may be formed of a negative photoresist layer having the response characteristic C of the second photoresist layer as described above with reference to FIG. 4B. Accordingly, an exposure reaction of the second photoresist layer 125 may be terminated or saturated at a threshold dose Dnc1 equal to or less than the reaction initiating dose Dpo1 of the first photoresist patterns 120. In this case, exposure reactions of the first photoresist patterns 120 may be initiated at a dose more than the threshold dose of the second photoresist layer 125, so that additional exposure of the first photoresist patterns 120 can be suppressed even when an exposure process is carried out on the second photoresist layer 125.

In some embodiments, the first photoresist patterns 120 and the second photoresist layer 125 can be formed of negative photoresist layers having the response characteristic D of the first photoresist layer and the response characteristic E of the second photoresist layer, respectively, as described above with reference to FIG. 5A. Accordingly, an exposure reaction of the second photoresist layer 125 may be initiated at a dose equal to or more than the threshold dose of the first photoresist patterns 120, and may be terminated or saturated at a threshold dose of the second photoresist layer shown in FIG. 5A. That is, the exposure process of the second photoresist layer 125 may enable the first photoresist patterns 120 to be substantially cured or further stabilized.

A light source used for the second exposure process (block S450 of FIG. 30) may be the same as the light sources for the first exposure process (block S200 of FIG. 3). For example, when the ArF laser is employed as the light source in the first exposure process, it can also be employed in the second exposure process.

Subsequently, a second post-exposure bake may be carried out on the second photoresist layer 125 having the second exposure regions 127 and 229 and the second non-exposed regions 129 and 227 (block S500 of FIG. 3). The second post-exposure bake (block S500 of FIG. 3) may be performed at a temperature lower than the temperature of the first soft bake and the temperature of the first post-exposure bake. This lower tempterature may minimize effects due to the temperature of the first photoresist patterns 120. In this case, the temperature of the second post-exposure bake may be above a minimum temperature desired for baking. That is, the second post-exposure bake can be performed at a temperature lower than the temperature of the first soft bake and the temperature of the first post-exposure bake, and can be performed, for example at a temperature of 90° C. or more.

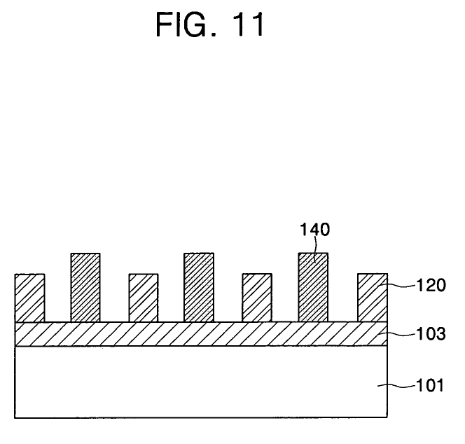

Referring to FIGS. 3 and 11, a second development process is performed on the second photoresist layer 125 in a region where the second exposure process (block S450) is performed (block S550 of FIG. 3). As a result, second photoresist patterns 140 may be formed between the first photoresist patterns 120. More particularly, when the second photoresist layer 125 is formed of a positive photoresist layer, the photoresist layer of the second exposed region 127 may be removed by the second development process (block S550 of FIG. 3), and only the photoresist layer of the second non-exposed region 129 remains, thereby forming the second photoresist patterns 140. On the contrary, when the second photoresist layer 125 is formed of a negative photoresist layer, the photoresist layer of the second exposed region 229 remains after the second development process (block S550 of FIG. 3), and the photoresist layer of the second non-exposed region 227 is removed by the second development process, thereby forming the second photoresist patterns 140.

According to some embodiments of the present invention, two photolithography processes are performed using photoresist layers having different response characteristics from each other as described above with reference to FIGS. 4A, 4B, 5A and 5B. Consequently, first photoresist patterns and second photoresist patterns can be stably formed by the two photolithography processes. The positive photoresist layer and the negative photoresist layer can be properly combined and used in accordance with some embodiments of the present invention, so that various fine patterns such as a line and space pattern or a contact hole pattern can be formed. In some embodiments, when the first photoresist patterns 120 and the second photoresist patterns 140 are formed of positive photoresist layers, finer patterns than typical patterns which can be obtained in the same light source can be formed.

It has been described that the G-line, the I-line, the KrF laser and/or the ArF laser may be used as the light source in accordance with some embodiments of the present invention, however, the present invention is not limited thereto. For example, a deep ultra violet (DUV) including the KrF laser and the ArF laser, an E-beam, an X-ray, and/or an ion beam may be used as the light source of the present invention.

According to some embodiments of the present invention as described above, two photolithography processes can be carried out to form stabilized fine patterns. That is, first photoresist patterns formed by the first photolithography process may not be substantially affected by the second photolithography process. Consequently, finer patterns than patterns that can be typically implemented in the same light source can be formed while stabilized fine patterns where pattern defects do not substantially occur can be formed.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following Claims.

What is claimed is:

1. A method of forming fine patterns of a semiconductor device, comprising:
forming a positive first photoresist layer on a semiconductor substrate, including inititiating an exposure reaction at a first dose;
exposing and developing the first photoresist layer to form first photoresist patterns;
forming a second photoresist layer on a region of the semiconductor substrate including the first photoresist patterns, including terminating an exposure reaction at a second dose no greater than the first dose; and
exposing and developing the second photoresist layer to form second photoresist patterns between the first photoresist patterns.

2. The method of claim 1, wherein the second photoresist layer is either a positive photoresist layer or a negative photoresist layer.

3. The method of claim 1, wherein exposing and developing the first photoresist layer and exposing and developing the second photoresist layer including exposing the photoresist layers to a same type of light source.

4. The method of claim 3, wherein the type of light source comprises a G-line, an I-line, a KrF laser or an ArF laser.

5. The method of claim 1, wherein the first and second photoresist layers are formed of chemically amplified resist layers.

6. The method of claim 5, wherein the chemically amplified resist layers include a photo acid generator (PAG).

7. The method of claim 6, wherein the PAG within the first photoresist layer has a concentration lower than that of the PAG within the second photoresist layer.

8. The method of claim 5, wherein the second photoresist layer comprises a positive photoresist layer.

9. The method of claim 8, wherein the chemically amplified resist layers include a quencher.

10. The method of claim 9, wherein the quencher within the first photoresist layer has a concentration higher than that of the quencher within the second photoresist layer.

11. The method of claim 1, wherein the first and second photoresist layers are formed of resist layers for G-line or I-line.

12. The method of claim 11, wherein the resist layers for G-line or I-line include a photo acid compound (PAC).

13. The method of claim 12, wherein the PAC within the first photoresist layer has a concentration lower than that of the PAC within the second photoresist layer.

14. A method of forming fine patterns of a semiconductor device, comprising:
forming a negative first photoresist layer on a semiconductor substrate, including terminating an exposure reaction at a first dose;
exposing and developing the first photoresist layer to form first photoresist patterns;
forming a second photoresist layer on a region of the semiconductor substrate including the first photoresist patterns, including initiating an exposure reaction at a second dose no less than the first dose; and
exposing and developing the second photoresist layer to form second photoresist patterns between the first photoresist patterns.

15. The method of claim 14, wherein the second photoresist layer is either a positive photoresist layer or a negative photoresist layer.

16. The method of claim 14, wherein exposing and developing the first photoresist layer and exposing and developing the second photoresist layer including exposing the photoresist layers to a same type of light source.

17. The method of claim 16, wherein the type of light source comprises a G-line, an I-line, a KrF laser or an ArF laser.

18. The method of claim 14, wherein the first and second photoresist layers are formed of chemically amplified resist layers.

19. The method of claim 18, wherein the chemically amplified resist layers include a photo acid generator (PAG).

20. The method of claim 19, wherein the PAG within the first photoresist layer has a concentration lower than that of the PAG within the second photoresist layer.

21. The method of claim 14, wherein the first and second photoresist layers are formed of resist layers for G-line or I-line.

22. The method of claim 21, wherein the resist layers for G-line or I-line include a photo acid compound (PAC).

23. The method of claim 22, wherein the PAC within the first photoresist layer has a concentration lower than that of the PAC within the second photoresist layer.
